(19) United States
(12) Patent Application Publication
(10) Pub. No.: US 2024/0030317 A1
(43) Pub. Date: Jan. 25, 2024

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Heng-Wen TING, Pingtung County (TW); Ming-Hua YU, Hsinchu City (TW); Yee-Chia YEO, Hsinchu City (TW); Han-Yu TANG, Hsinchu (TW)

(73) Assignee: TAIWAN SEMICONDUCTOR MANUFACTURING COMPANY, LTD., Hsinchu (TW)

(21) Appl. No.: 17/869,205

(22) Filed: Jul. 20, 2022

(51) Int. Cl. H01L 29/66; H01L 21/8234; H01L 29/78; H01L 29/08

(52) U.S. Cl. CPC H01L 29/66795; H01L 21/823431; H01L 21/823418; H01L 21/823468; H01L 29/7851; H01L 29/0847

(57) ABSTRACT

A method for manufacturing a semiconductor device is provided. The method includes forming a semiconductor fin over a semiconductor substrate; forming a gate structure over a first portion of the semiconductor fin; etching a source/drain recess over a second portion of the semiconductor fin; and performing an in-situ source/drain etching and epitaxy process to form a source/drain epitaxial structure in the second portion of the semiconductor fin. The step of performing the in-situ source/drain etching and epitaxy process comprises performing a dry etching process to adjust a profile of the source/drain recess in a chamber; and after adjusting the dry etching process, epitaxially growing the source/drain epitaxial structure in the source/drain recess in the chamber.

### BACKGROUND

The semiconductor integrated circuit (IC) industry has experienced rapid growth. In the course of IC evolution, functional density (i.e., the number of interconnected devices per chip area) has generally increased while geometry size (i.e., the smallest component (or line) that can be created using a fabrication process) has decreased. This scaling down process provides benefits by increasing production efficiency and lowering associated costs.

Such scaling down has also increased the complexity of processing and manufacturing ICs and, for these advances to be realized, similar developments in IC processing and manufacturing are desired. For example, a three dimensional transistor, such as a fin-like field-effect transistor (FinFET), has been introduced to replace a planar transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9B illustrate a method of manufacturing a semiconductor device at various stages in accordance with some embodiments.

FIG. 10 illustrates a semiconductor device according to some embodiments of the present disclosure.

FIG. 11 illustrates a semiconductor device according to some embodiments of the present disclosure.

FIGS. 12A, 12B, and 13 illustrate a method of manufacturing a semiconductor device at various stages in accordance with some embodiments.

FIGS. 14A, 14B, and 15 illustrate a method of manufacturing a semiconductor device at various stages in accordance with some embodiments.

FIG. 16 is a schematic view of an apparatus for the in-situ etching and epitaxy process according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to, but not otherwise limited to, a FinFET device. The FinFET device, for example, may be a complementary metal-oxide-semiconductor (CMOS) device comprising a P-type metal-oxide-semiconductor (PMOS) FinFET device and an N-type metal-oxide-semiconductor (NMOS) FinFET device. The following disclosure will continue with a FinFET example to illustrate various embodiments of the present disclosure. It is understood, however, that the application should not be limited to a particular type of device, except as specifically claimed.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. Source/drain region(s) may refer to a source or a drain, individually or collectively dependent upon the context.

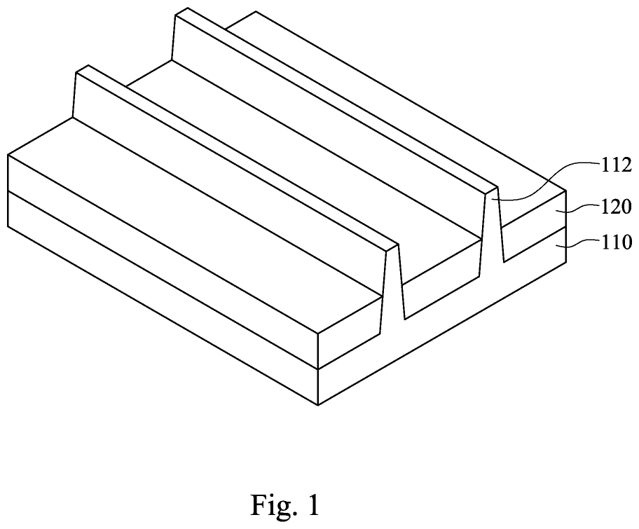

FIGS. 1-9B illustrate a method of manufacturing a semiconductor device at various stages in accordance with some embodiments. It is understood that additional steps may be provided before, during, and after the steps shown in FIGS. 1-9B, and some of the steps described below can be replaced or eliminated for additional embodiments of the method. The order of the operations/processes may be interchangeable.

Reference is made to FIG. 1. A substrate 110 including plural semiconductor fins 112 is provided. The substrate 110 may be a bulk silicon substrate. Alternatively, the substrate 110 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. Possible substrates 110 also include a silicon-on-insulator (SOI) substrate. SOI substrates are fabricated using separation by implantation of oxygen (SIMOX), wafer bonding, and/or other suitable methods.

The substrate 110 may also include various doped regions. The doped regions may be doped with p-type dopants, such as boron or BF₂; n-type dopants, such as phosphorus or arsenic; or combinations thereof. The doped regions may be formed directly on the substrate 110, in a P-well structure, in an N-well structure, in a dual-well structure, and/or using a raised structure. The substrate 110 may further include various active regions, such as regions configured for an N-type metal-oxide-semiconductor transistor device and regions configured for a P-type metal-oxide-semiconductor transistor device.

The semiconductor fins 112 may be formed by any suitable method. For example, the semiconductor fins 112 may be formed by using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

A plurality of isolation structures 120 are formed over the substrate 110 and interposing the semiconductor fins 112. The isolation structures 120 may act as a shallow trench isolation (STI) around the semiconductor fins 112. The isolation structures 120 may be formed by depositing a dielectric material around the fins 112, followed by a recessing etching process that lowers top surfaces of the dielectric material. In some embodiments, a dielectric layer is first deposited over the substrate 110, filling the trenches between the fins 112 with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, an ALD process, a physical vapor deposition (PVD) process, and/or other suitable process. In some embodiments, after deposition of the dielectric layer, the structure may be annealed, for example, to improve the quality of the dielectric layer. In some embodiments, the dielectric layer (and subsequently formed isolation structures 120) may include a multi-layer structure, for example, having one or more liner layers.

After deposition of the dielectric layer, the deposited dielectric material may be thinned and planarized, for example by a chemical mechanical polishing (CMP) process. Subsequently, the isolation structures 120 interposing the fins 112 may be recessed. For example, the isolation structures 120 are recessed providing the fins 112 extending above the isolation structures 120. In some embodiments, the recessing process may include a dry etching process, a wet etching process, and/or a combination thereof. In some embodiments, a recessing depth is controlled (e.g., by controlling an etching time) so as to result in a desired height of the exposed upper portion of the fins 112.

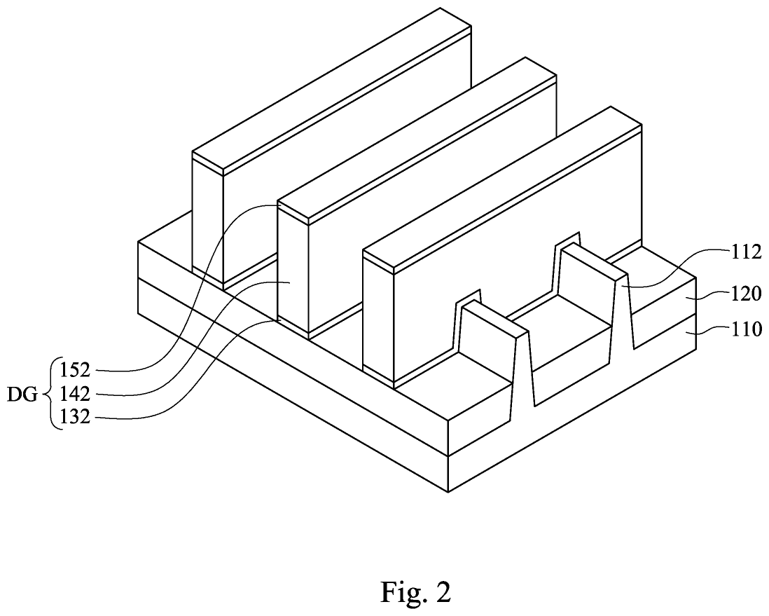

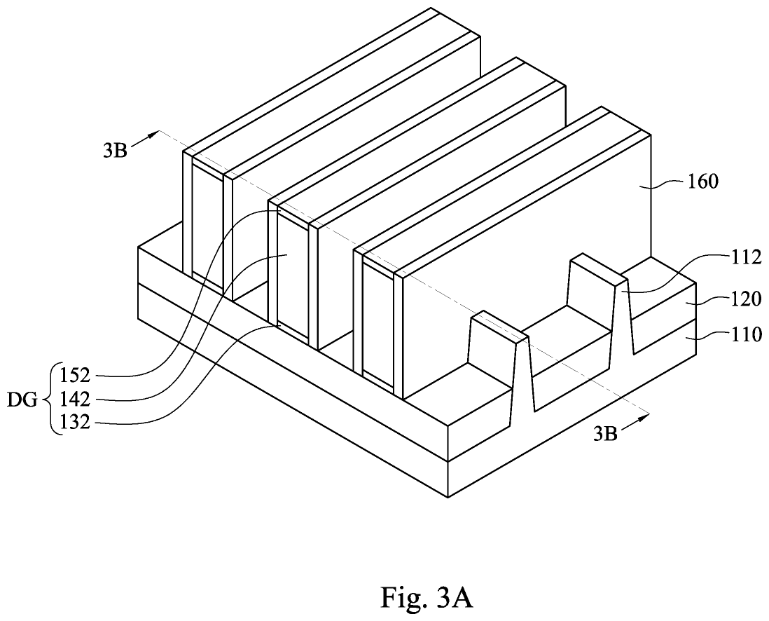

Reference is made to FIG. 2. A plurality of dummy gate structures DG are formed around the semiconductor fins 112 of the substrate 110. In some embodiments, each of the dummy gate structure DG includes a dummy gate 142 and a gate dielectric 132 underlying the dummy gate 142. The dummy gates 142 may include polycrystalline-silicon (poly-Si) or poly-crystalline silicon-germanium (poly-SiGe). Further, the dummy gates 142 may be doped poly-silicon with uniform or non-uniform doping. The gate dielectrics 132 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof.

In some embodiments, the dummy gate structures DG may be formed by, for example, forming a stack of a gate dielectric layer and a dummy gate material layer over the substrate 110. A patterned mask 152 is formed over the stack of gate dielectric layer and dummy gate material layer. The patterned mask 152 may be a hard mask (HM) layer patterned through suitable photolithography process. For example, the patterned mask 152 may include silicon nitride, silicon oxy nitride, the like, or the combination thereof. Then, the gate dielectric layer and the dummy gate material layer may be patterned using one or more etching processes, such as one or more dry plasma etching processes or one or more wet etching processes. During the etching process, the patterned mask 152 may act as an etching mask. At least one parameter, such as etchant, etching temperature, etching solution concentration, etching pressure, source power, radio frequency (RF) bias voltage, etchant flow rate, of the patterning (or etching) recipe can be tuned. For example, dry etching process, such as plasma etching, may be used to etch the dummy gate material layer and the gate dielectric layer until the semiconductor fins 112 are exposed.

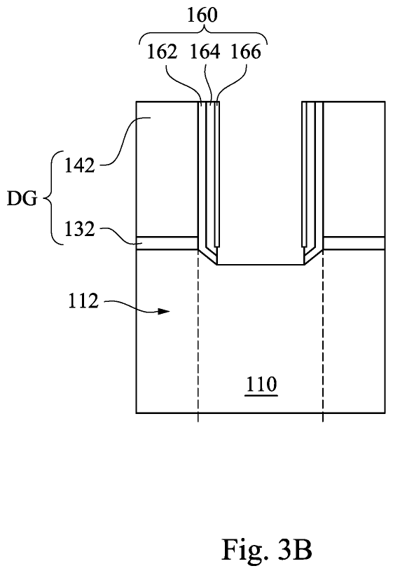

Reference is made to FIGS. 3A and 3B. FIG. 3B is a cross-sectional view taken along line 3B-3B in FIG. 3A. In some embodiments of formation of the gate spacers 160, a spacer material layer is first deposited over the substrate 110. The spacer material layer may be a conformal layer that is subsequently etched to form gate spacers 160 on sidewalls of the dummy gate structures DG. In the illustrated embodiment, a spacer material layer is disposed conformally on top and sidewalls of the dummy gate structures DG. The spacer material layer may include a dielectric material such as silicon oxide, silicon nitride, silicon oxynitride, SiCN films, silicon oxycarbide, SiOCN films, and/or combinations thereof. In some embodiments, the spacer material layer includes multiple layers, such as a first spacer layer 162, a second spacer layer 164 formed over the first spacer layer 162, and a third spacer layer 166 formed over the first spacer layer 162. The first to third spacer layers may include the same or different dielectric materials. By way of example, the spacer material layer may be formed by depositing a dielectric material over the gate structures DG using processes such as, CVD process, a subatmospheric CVD (SACVD) process, a flowable CVD process, an ALD process, a PVD process, or other suitable process. An anisotropic etching process is then performed on the deposited spacer material layer to expose portions of the fins 112 not covered by the dummy gate structures DG (e.g., in source/drain regions of the fins 112). Portions of the spacer material layer directly above the dummy gate structures DG may be completely removed by this anisotropic etching process. Portions of the spacer material layer on sidewalls of the dummy gate structures DG may remain, forming gate spacers, which are denoted as the gate spacers 160, for the sake of simplicity. In some embodiments, the gate spacers 160 may be a single-layer structure or a multi-layer structures that includes multiple layers. It is noted that although the gate spacers 160 are multi-layer structures in the cross-sectional view of FIG. 3B, they are illustrated as single-layer structures in the perspective view of FIG. 3A for the sake of simplicity.

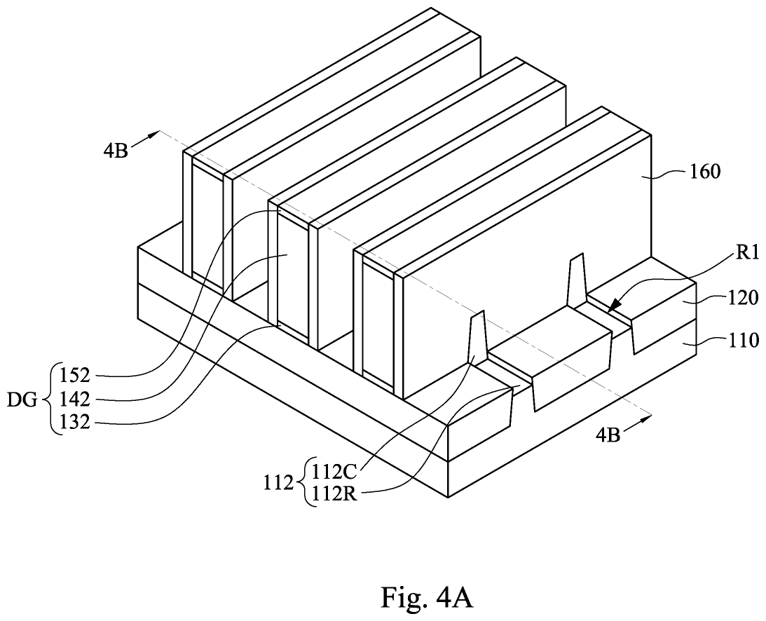

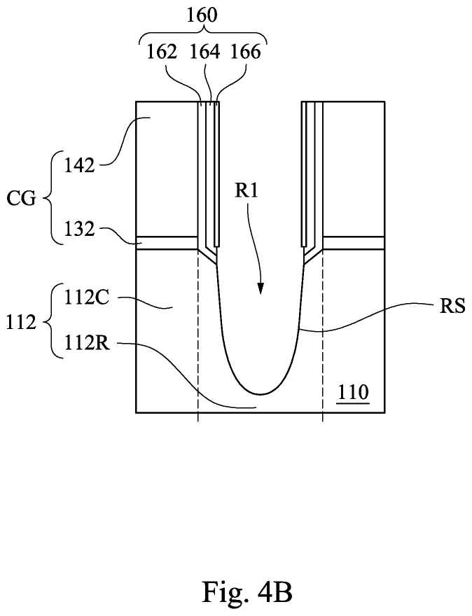

Reference is made to FIGS. 4A and 4B. FIG. 4B is a cross-sectional view taken along line 4B-4B in FIG. 4A. Portions of the semiconductor fins 112 uncovered by the dummy gate structures DG are removed, such that each of the remaining semiconductor fins 112 include a recessed portion 112R uncovered by the dummy gate structures DG and a channel portion 112C covered by the dummy gate structures DG, respectively. Through the removal, a plurality of recesses R1 are formed in the semiconductor fins 112 of the substrate 110. The removal of the semiconductor fins 112 may include a selective dry etching process. The dry etching processes may include a biased plasma etching process that uses a fluorine-based chemistry (e.g., CF₄, SF₆, CH₂F₂, CHF₃, and/or C₄F₈). Dry etching may also be performed anisotropically using such mechanisms as DRIE (deep reactive-ion etching). The anisotropic etching process may result in little lateral etching.

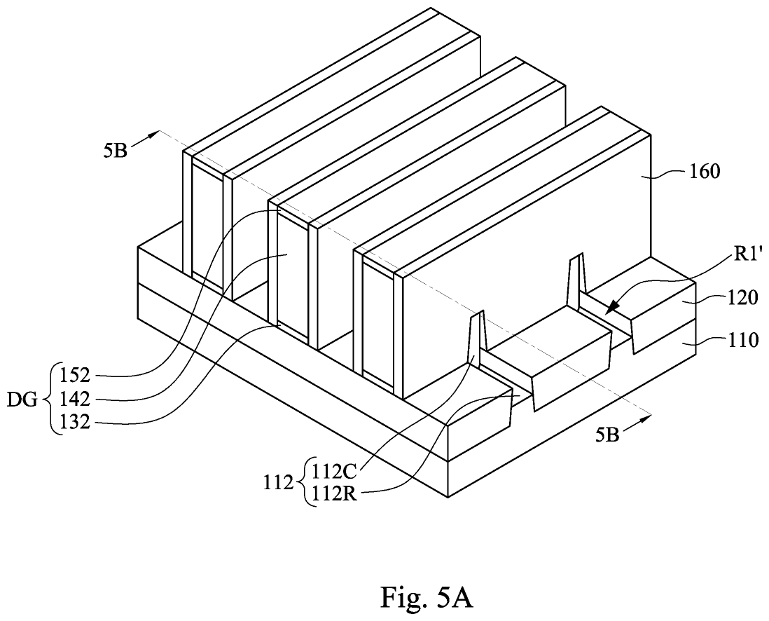

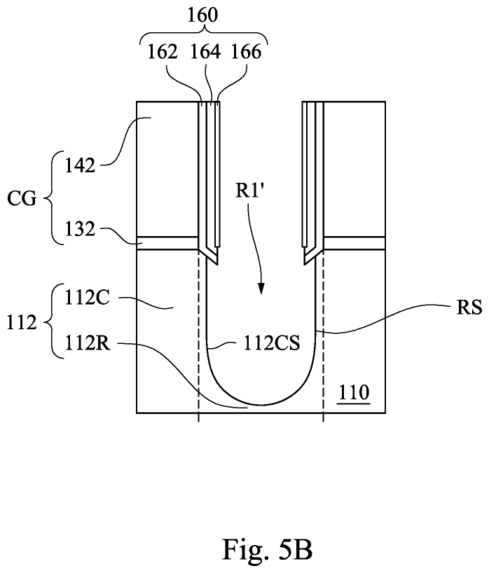

Reference is made to FIGS. 5A and 5B. FIG. 5B is a cross-sectional view taken along line 5B-5B in FIG. 5A. A recess modifying etching process is performed to adjust the profile of the recesses R1 (referring to FIGS. 4A and 4B). For example, the recess R1 is deepened, and the sidewall RS of the recess R1 (referring to FIGS. 4A and 4B) is pushed toward the channel portion 112C. The modified recesses R1 (referring to FIGS. 4A and 4B) are referred to as recesses RP. In the present embodiments, the recesses R1′ may have a substantially U-shaped profile, and a sidewall RS of the recess R1′ can be directly below the gate spacer 160 and deviated from inner and outer edges (or inner and outer boundaries) of the gate spacer 160. For example, the sidewalls 112CS of the channel portions 112C may be vertical, directly below the gate spacer 160 and deviated from inner and outer edges (or inner and outer boundaries) of the gate spacer 160. In some embodiments, the substantially U-shaped recesses R1′ can be formed with an etching process where etching parameters thereof are tuned (such as etchants used, etching temperature, etching pressure, source power, radio frequency (RF) bias voltage, RF bias power, etchant flow rate, and other suitable parameters) to achieve the predetermined recess profile. In some other embodiments, the recesses R1′ may have other shapes, such as diamond shape, a semi-elliptical-like shape, a rectangular-like shape or irregular shapes.

In some embodiments, for achieving the desired profile (e.g., substantial U-shape), the recess modifying etching process may be performed by a dry etch with suitable process parameters (such as process gases used, temperature, pressure, and other suitable parameters). In some embodiments, the recess modifying etching process may be performed in a temperature ranging from about 400° C. to about 700° C., or from about 560° C. to about 620° C. If the temperature is less than about 400° C., the semiconductor materials at sidewalls of the recess R1 (referring to FIGS. 4A and 4B) may not be etched. If the temperature is greater than about 700° C., the modified recess R1′ may not have the desired recess profile. In some embodiments, the recess modifying etching process may be performed at a pressure ranging from about 10 torr to about 300 torr, or from about 100 torr to about 200 torr. If the pressure is less than about 10 torr, the semiconductor materials at sidewalls of the recess R1 (referring to FIGS. 4A and 4B) may not be etched. If the pressure is greater than about 300 torr, the modified recess R1′ may not have the desired recess profile. In the recess modifying etching process, the recess modifying etching process may be performed using gas-phase etchants without using plasma. For example, the gas-phase etchants may include chlorine-based chemistry (e.g., HCl, Cl₂), GeH₄, GeCl₄, the like, or the combination thereof. In some embodiments, the recess modifying etching process (referring to FIGS. 5A and 5B) etches materials more isotopically than the etching process for the recess R1 (referring to FIGS. 4A and 4B) does. In other words, a degree of anisotropy of the etching process for the recess R1 (referring to FIGS. 4A and 4B) is greater than a degree of anisotropy of the recess modifying etching process (referring to FIGS. 5A and 5B).

In some other embodiments, the recess modifying etching process may be performed with a dry etch, a wet etch, or the combination thereof. The dry etching processes may use a chlorine-based chemistry (e.g., HCl, and Cl₂) with or without a biased plasma etching. The wet etching processes may use wet etching solution including NH₄OH, KOH (potassium hydroxide), HF (hydrofluoric acid), TMAH (tetramethylammonium hydroxide), other suitable wet etching solutions, or combinations thereof. At least one parameter, such as etchant, etching temperature, etching solution concentration, etching pressure, source power, radio frequency (RF) bias voltage, etchant flow rate, of the etching recipe can be tuned for desired profile.

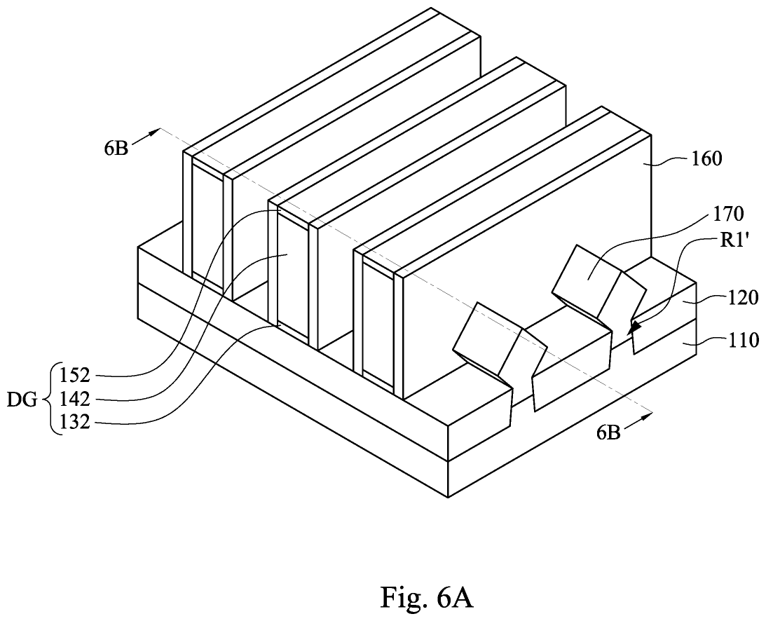

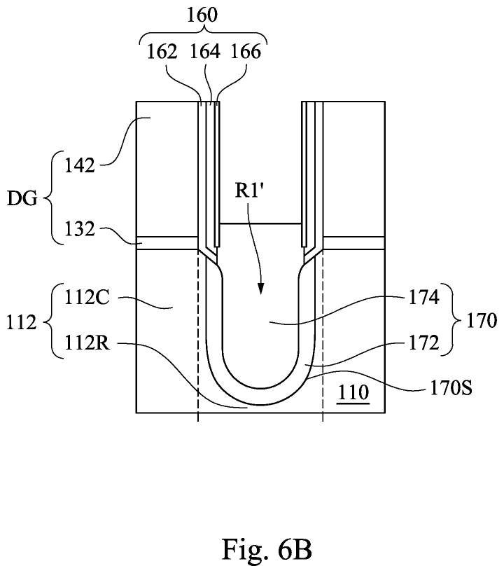

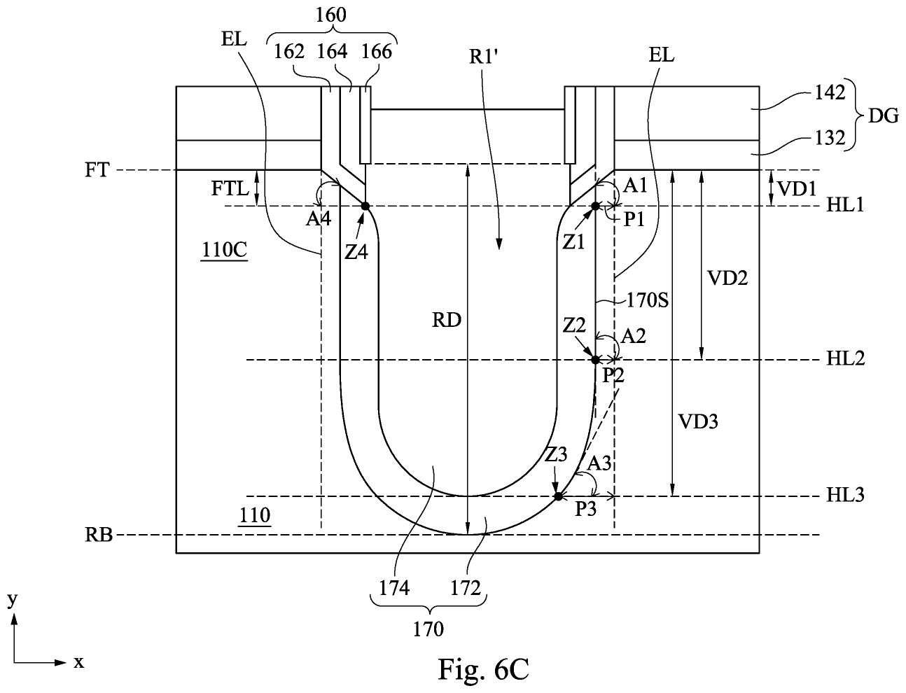

Reference is made to FIGS. 6A and 6B. FIG. 6B is a cross-sectional view taken along line 6B-6B in FIG. 6A. A plurality of source/drain epitaxial structures 170 are respectively formed in the recesses R1′ of the semiconductor fins 112 of the substrate 110. At least one of the source/drain epitaxial structures 170 is formed in the recess R1′ and between the dummy gate structures DG. In some embodiments, according to the shape of the recess RP, the source/drain epitaxial structures 170 may have a U-shape. In the present embodiments, a sidewall 170S of the source/drain epitaxial structures 170 can be directly below the gate spacer 160 and deviated from inner and outer edges (or inner and outer boundaries) of the gate spacer 160.

In some embodiments, the source/drain epitaxial structures 170 may also be referred to as epitaxy features. The source/drain epitaxial structures 170 may be formed using one or more epitaxy or epitaxial (epi) processes, such that Si features, SiGe features, and/or other suitable features can be formed in a crystalline state on the semiconductor fins 112. In some embodiments, lattice constants of the source/drain epitaxial structures 170 are different from lattice constants of the semiconductor fins 112, such that channels in the channel portions 112C of the semiconductor fins 112 are strained or stressed to enable carrier mobility of the semiconductor device and enhance the device performance. In some embodiments, the source/drain epitaxial structures 170 may include semiconductor material such as germanium (Ge) or silicon (Si); or compound semiconductor materials, such as gallium arsenide (GaAs), aluminum gallium arsenide (AlGaAs), silicon germanium (SiGe), silicon carbide (SiC), or gallium arsenide phosphide (GaAsP). In some embodiments, the source/drain epitaxial structures 170 may include one or plural epitaxial layers, in which the plural epitaxial layers may have different compositions. For example, the source/drain epitaxial structures 170 is depicted as including a first epitaxial layer 172 and a second epitaxial layer 174, in which a composition of the first epitaxial layer 172 is different from that of the second epitaxial layer 174.

The epitaxy processes include CVD deposition techniques (e.g., vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor fins 112 (e.g., silicon). The source/drain epitaxial structures 170 may be in-situ doped. The doping species include p-type dopants, such as boron or BF₂; n-type dopants, such as phosphorus or arsenic; and/or other suitable dopants including combinations thereof. If the source/drain epitaxial structures 170 are not in-situ doped, a second implantation process (i.e., a junction implant process) is performed to dope the source/drain epitaxial structures 170. One or more annealing processes may be performed to activate the source/drain epitaxial structures 170. The annealing processes include rapid thermal annealing (RTA) and/or laser annealing processes.

In some embodiments, the recess modifying etching process includes a dry etch, and the recess modifying etching process and the formation of the source/drain epitaxial structures 170 may be performed by in-situ etching and epitaxy process. That is, recessing the fins 112 and the formation of the source/drain epitaxial structures 170 are performed in a same processing chamber, with no vacuum break therein. For example, a gas-phase etchant (e.g., Cl₂, HCl, GeH₄, and/or GeCl₄)) is introduced into the processing chamber for etching semiconductor materials at sidewalls of the recess R1 (referring to FIGS. 4A and 4B), thereby adjusting the profile the recess R1 (referring to FIGS. 4A and 4B) to be the profile of the recess R1′. Subsequently, one or more semiconductor-containing precursors are introduced into the processing chamber for selectively growing the source/drain epitaxial structures 170 in the recess R1′. The semiconductor-containing precursors may contain one or more semiconductor materials of source/drain epitaxial structures 170. Introducing the gas-phase etchant and the semiconductor-containing precursor for selectively growing may be performed with no vacuum break therein. Through the in-situ etching and epitaxy process, surface impurity residue can be avoided. Thus, the source/drain epitaxial structures 170 can be formed with better surface roughness, and lower interface impurity.

In some other embodiments, the recess modifying etching process may be performed by ex-situ etching, and then the formation of the source/drain epitaxial structures 170 is performed by epitaxy process. In other words, the recess modifying etching process is not performed in the same chamber where the source/drain epitaxial structures 170 is formed. For example, as mentioned above, the recess modifying etching process may be performed with a wet etch or a combination of a wet etch and a dry etch.

FIG. 6C is a enlarge view of a portion of FIG. 6B. The profile of the recess R1′ and/or the source/drain epitaxial structures 170 can be at least described by push values at various levels (e.g., push values P1, P2, and P3 at three levels) in a XY coordinate system, which may be defined by two axes x and y at right angles to each other. In some embodiments, each of the push values (e.g., push values P1, P2, and P3) is a result of subtracting an x-coordinate of a point (e.g., points Z1, Z2, and Z3) at the sidewall RS/170S from an x-coordinate of a dashed line EL. The push values can also be referred to as a lateral difference, a horizontal difference, or an x difference between an x-coordinate of the point (e.g., push values Z1, Z2, and Z3) and an x-coordinate of the dashed line EL. For example, the push value P1 is a result of subtracting an x-coordinate of the point Z1 from the x-coordinate of the dashed line EL. The push value P2 is a result of subtracting an x-coordinate of the point Z2 from the x-coordinate of the dashed line EL. The push value P3 is a result of subtracting an x-coordinate of the point Z3 from the x-coordinate of the dashed line EL. For example, in the XY coordinate system, the points Z1, Z2, and Z3 are respectively at (x₁, y₁), (x₂, y₂), and (x₃, y₃), the right dashed′ line EL is at x=x₀, and the push values P1, P2, and P3 are respectively represented as (x₀−x₁), (x₀−x₂), and (x₀−x₃). In the context, the dashed lines EL may indicate interfaces between the dummy gate structures DG and the gate spacer 160 are indicated. Sometimes, the dashed line EL may also indicate sidewalls of the dummy gate structures DG adjoining the gate spacers 160, or a sidewall of the gate spacer 160 adjoining the dummy gate structures DG. The axis x may be substantially parallel to a top surface of the substrate 110, and the axis y may be substantially normal to a top surface of the substrate 110.

In FIG. 6C, a position of a top of the fin 112 is indicated by a dashed fin top line FT, and a position of a bottom of the recess R1 is indicated by a dashed recess bottom line RB. The recess R1′ may have a recess depth RD, which is equal to a vertical distance from the dashed fin top line FT to the dashed recess bottom line RB. The points Z1, Z2, Z3 at the sidewalls RS/170S are respectively at vertical distances VD1, VD2, and VD3 from the fin top line FT, in which the vertical distance VD1, VD2, and VD3 are respectively equal to the recess depth RD multiplied by a first ratio, a second ratio, and a third ratio. For example, the first ratio may be in a range from about 0.1% to about 5%, such as about 0.5%. The second ratio may be in a range from about 40% to about 60%, such as about 50%. The third ratio may be in a range from about 70% to about 90%, such as about 80%. The recess depth RD may be in a range from about 30 nanometers to about 70 nanometers in some embodiments. If the recess depth RD is less than about 30 nanometer or greater than about 70 nanometers, the device electrical performance may degrade.

In some embodiments of the present disclosure, the push value P1 may be in a range from about −5 nanometers to about 10 nanometers, the push value P2 may be in a range from about −5 nanometers to about 10 nanometers, and the push value P3 may be in a range from about 0 nanometer to about 15 nanometers. When the push value (e.g., the push value P1 and/or P2) is negative, the point at the sidewall RS/170S (e.g., the point Z1 and/or Z2) is beyond the edge of the dummy gate structures DG (i.e., dashed line GE) and directly below the dummy gate structures DG. When the push value (e.g., the push value P1, P2, and/or P3) is zero, the point at the sidewall RS/170S (e.g., the point Z1, Z2, and/or Z3) is aligned with respect to the edge of the dummy gate structures DG (i.e., dashed line GE). When the push value (e.g., the push value P1, P2, and/or P3) is negative, the point at the sidewall RS/170S (e.g., the point Z1, Z2, and/or Z3) is away from the edge of the dummy gate structures DG (i.e., dashed line GE) and not directly below the dummy gate structures DG. If the push value P1 is less than about −5 nanometers, a drain-induced barrier lowering (DIBL) may be increased, thereby degrading the device electrical performance. If the push value P1 is greater than about 10 nanometers, a resulted channel resistance may be too large, thereby degrading the device electrical performance. If the push value P2 is less than about −5 nanometers, a drain-induced barrier lowering (DIBL) may be increased, thereby degrading the device electrical performance. If the push value P2 is greater than about 10 nanometers, a resulted channel resistance may be too large, thereby degrading the device electrical performance. If the push value P3 is less than about 0 nanometer, a drain-induced barrier lowering (DIEL) may be increased, thereby degrading the device electrical performance. If the push value P3 is greater than about 15 nanometers, a resulted channel resistance may be too large, thereby degrading the device electrical performance.

In some embodiments of the present disclosure, a difference between the push values P1 and P2 is less than 5 nanometers, and a difference between the push values P2 and P3 is less than 15 nanometers. That is, a result of subtracting the push value P2 from the push value P1 is in a range from about-5 nanometers to about 5 nanometers, and a result of subtracting the push value P3 from the push value P2 is in a range from about −15 nanometers to about 15 nanometers. If the result of subtracting the push value P2 from the push value P1 is less than about −5 nanometers or greater than about 5 nanometers, the device electrical performance may be degraded. If the result of subtracting the push value P3 from the push value P2 is less than about −15 nanometers or greater than about 15 nanometers, the device electrical performance may be degraded.

In some embodiments, in addition to the plural levels of push values (e.g., the push values P1, P2, and P3), the profile of the recess R1′ and/or the source/drain epitaxial structures 170 can further be described by angles at various levels, in which each of the angles is between a tangent line to the sidewall RS/170S at a point and a horizontal line passing through the point. For example, in the present embodiments, the profile of the recess R1′ and/or the source/drain epitaxial structures 170 can be further described by angles A1, A2, and A3 at three levels. The angle A1 is between a tangent line to the sidewall RS/170S at the point Z1 and a horizontal plane HL1 passing through the point Z1. The angle A2 is between a tangent line to the sidewall RS/170S at the point Z2 and a horizontal plane HL2 passing through the point Z2. The angle A3 is between a tangent line to the sidewall RS/170S at the point Z3 and a horizontal plane HL3 passing through the point Z3.

In some embodiments of the present disclosure, the angle A1 may be in a range from about 45° to about 135°, the angle A2 may be in a range from about 90° to about 135°, and the angle A3 may be in a range from about 45° to about 90°. If the angle A1 is greater than about 135° or less than about 45°, the device electrical performance may be degraded. If the angle A2 is greater than about 135° or less than about 90°, the device electrical performance may be degraded. If the angle A3 is greater than about 90° or less than about 45°, the device electrical performance may be degraded.

In some embodiments, a bottom surface of the gate spacer 160 is inclined with respect to a top surface of the semiconductor substrate 110. An angle A4 is between the tangent line to the bottom surface of the gate spacer 160 at the point Z4 and a horizontal plane passing through the point Z4 (e.g., the plane HL1 in the present embodiments). The point Z4 indicates a bottom end of the gate spacer 160. In some embodiments of the present disclosure, the angle A4 may be in a range from about 5° to about 85°. If the angle A4 is less than about 5° or greater than about 85°, the device electrical performance may be degraded. In the present embodiments, the plane HL1 is level with the bottom end of the gate spacer 160 (i.e. point Z4). In some other embodiments the plane HL1 may be higher than or lower than the bottom end of the gate spacer 160 (i.e. point Z4).

A fin-top loss FTL is a vertical length/distance from the bottom end of the gate spacer 160 to the fin top line FT. In some embodiments of the present disclosure, the fin-top loss FTL may be in a range from about 0.3 nanometer to about 10 nanometers. If the fin-top loss FTL is less than about 0.3 nanometer or greater than about 10 nanometers, the device electrical performance may be degraded. In the figures, the dashed fin top line FT and the dashed recess bottom line RB may indicate planes substantially parallel with the top surface of the substrate 110. The horizontal planes HL1, HL2, and HL3 may be substantially parallel with the top surface of the substrate 110. Therefore, the dashed fin top line FT, the dashed recess bottom line RB, and horizontal planes HL1, HL2, and HL3 may be substantially parallel with each other.

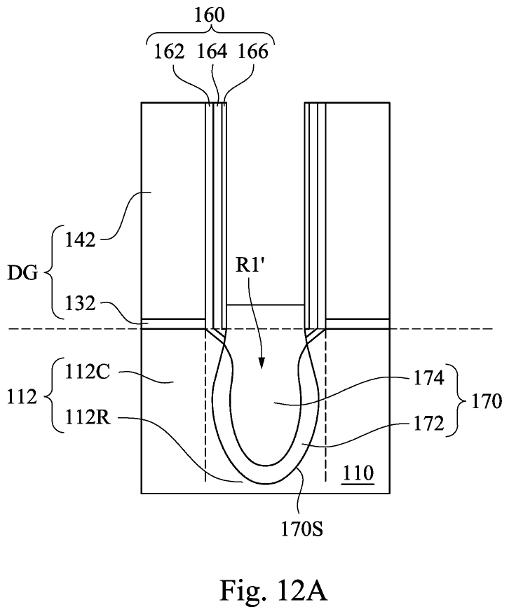

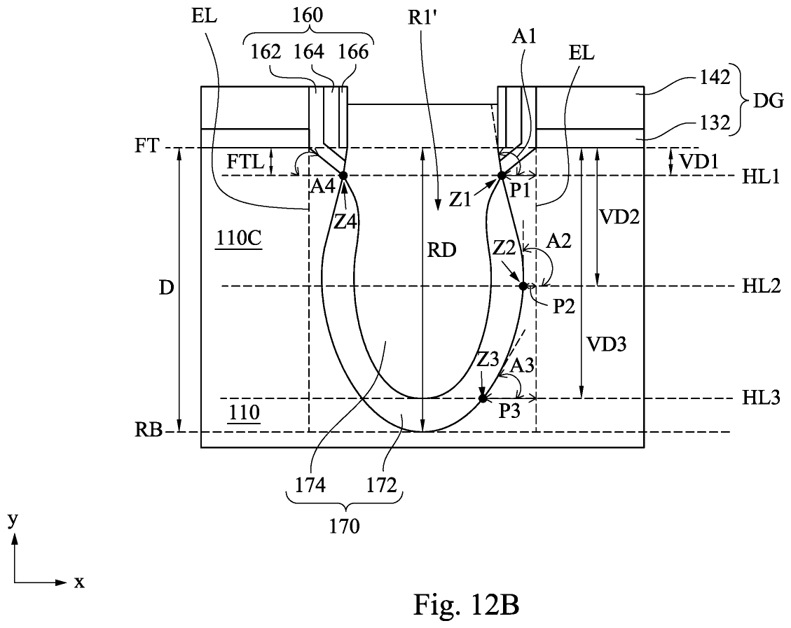

As shown in FIG. 6C, the source/drain epitaxial structure 170 may have a U-shape. For example, the middle width of the source/drain epitaxial structure 170 (e.g., measured at a plane HL2) is substantially equal to the top width the source/drain epitaxial structure 170 (e.g., measured at a plane HL1). In some embodiments, the plane HL2 is at a vertical middle between a bottom of the source/drain epitaxial structure 170 and a top of the semiconductor fin 112. In the present embodiments, the push value P1 is positive, the push value P1 is substantially equal to the push value P2, within a tolerance range of 10%. For example, a result of subtracting the push value P2 from the push value P1 is in a range from −10% of an absolute value of the push value P1/P2 to about 10% of the absolute value of the push value P1/P2. In some embodiments of FIG. 6C, the push value P1, P2, P3 may be respectively ranging from about 0 nanometer to about 10 nanometers, about 0 nanometer to about 10 nanometers, and about 0 nanometer to about 15 nanometers, in which a difference between the push values P1 and P2 may be less than 3 nanometers, and a difference between the push values P2 and P3 may be less than 10 nanometers. With the configuration, a top end of the sidewall 170S of the source/drain epitaxial structure 170 may be in contact with a bottom surface of the gate spacer 160. In some other embodiments, the push value P1 is negative, and the push value P1 is substantially equal to the push value P2, within a tolerance range of 10%. In some other embodiments, the source/drain epitaxial structure 170 may have other shapes, and the push value P1 can be greater than or less than the push value P2, as illustrated in FIGS. 12A-13 and FIGS. 14A-15 later.

Reference is made to FIG. 7. After the source/drain epitaxial structures 170 are formed, an interlayer dielectric (ILD) 190 is formed over the substrate 110 and surrounding the source/drain epitaxial structures 170. The ILD 190 may include silicon oxide, oxynitride or other suitable materials. The ILD 190 includes a single layer or multiple layers. The ILD 190 can be formed by a suitable technique, such as CVD or ALD. A chemical mechanical polishing (CMP) process may be performed to remove an excess portion of the ILD 190 until reaching the dummy gate structures DG. After the chemical mechanical planarization (CMP) process, the dummy gate structures DG are exposed from the ILD 190. In some embodiments, a contact etch stop layer (CESL) 180 may be blanket formed over the substrate 110 prior to the formation of the ILD 190. In some examples, the CESL 180 includes a silicon nitride layer, silicon oxide layer, a silicon oxynitride layer, and/or other suitable materials having a different etch selectivity than the ILD 190. The CESL 180 may be formed by plasma-enhanced chemical vapor deposition (PECVD) process and/or other suitable deposition or oxidation processes. In some embodiments, prior to the formation of the CESL 180, or during the source/drain recessing process (e.g., the in-situ etching and epitaxy process), a portion of the gate spacer 160 (e.g., the spacer layer 166 shown in FIG. 6B) may be consumed and removed, for example, by suitable cleaning or etching process.

Reference is made to FIG. 8. A replacement gate (RPG) process scheme is employed. The dummy gate structures DG are replaced with gate stacks GS. For example, the dummy gate structures DG (see FIG. 7) are removed to form a plurality of gate trenches. The dummy gate structures DG are removed by a selective etch process, including a selective wet etch or a selective dry etch, and carries a substantially vertical profile of the gate spacers 140. The gate trenches expose portions of the semiconductor fins 112 of the substrate 110. Then, the gate stacks GS are formed respectively in the gate trenches and cover the semiconductor fins 112 of the substrate 110. The gate stack GS may include a gate dielectric layer and a metal-containing layer 220 over the gate dielectric layer.

The gate dielectric layer may include an interfacial layer 200 and a high-k dielectric layer 210 over the interfacial layer 200. The interfacial layer 200 may include silicon oxides, for example, formed by thermal oxidation process. The high-k dielectric layers 210, as used and described herein, include dielectric materials having a high dielectric constant, for example, greater than that of thermal silicon oxide (˜3.9). The high-k dielectric layers 210 may include a high-K dielectric layer such as tantalum, hafnium, titanium, lanthanum, aluminum and their carbide, silicide, nitride, boride combinations. The high-k dielectric layers 210 may include other high-K dielectrics, such as HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AISiO, HfTaO, HfTiO, (Ba,Sr)TiO₃ (BST), Al₂O₃, Si₃N₄, oxynitrides (SiON), combinations thereof, or other suitable material. The high-k dielectric layers 210 may be formed by ALD, PVD, CVD, oxidation, and/or other suitable methods. In some embodiments, the high-k dielectric layers 210 may include the same or different materials.

The metal-containing layer 220 may include a metal, metal alloy, metal carbide, metal silicide, metal carbide silicide, metal carbide nitride, and/or metal boride. In some embodiments, the metal-containing layer 220 may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicide. For example, the metal-containing layer 220 may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAIN, TaC, TaCN, TaSiN, Mn, Zr, other suitable n-type work function materials, or combinations thereof. The work function layer may include a plurality of layers. The work function layer(s) may be deposited by CVD, PVD, electro-plating and/or other suitable process. In some embodiments, the multi-layer metal-containing layers 220 may include the same or different materials.

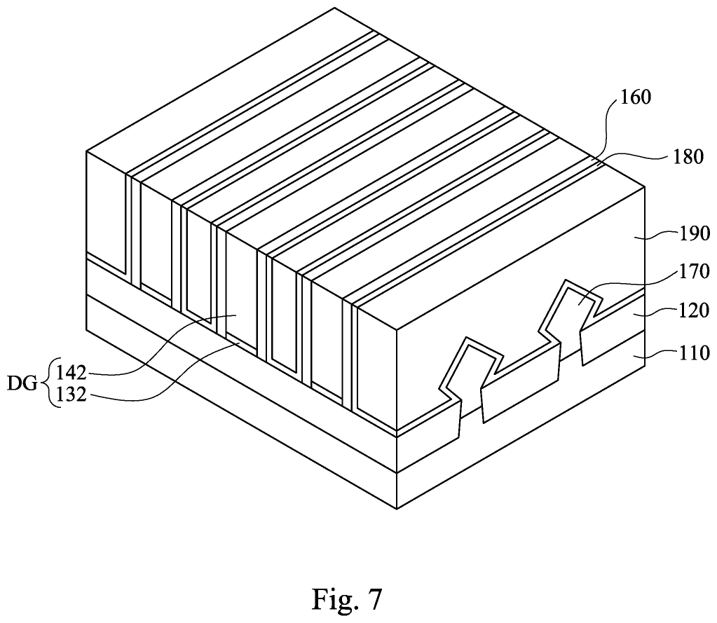

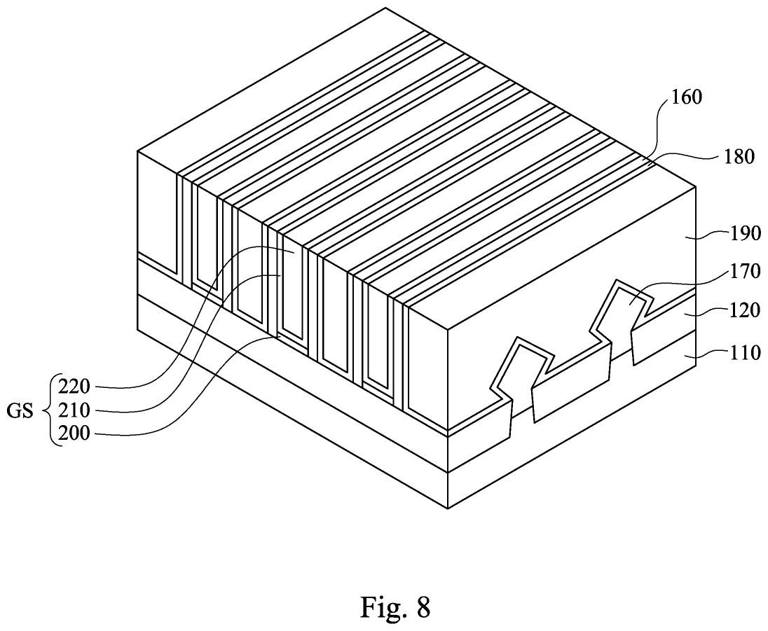

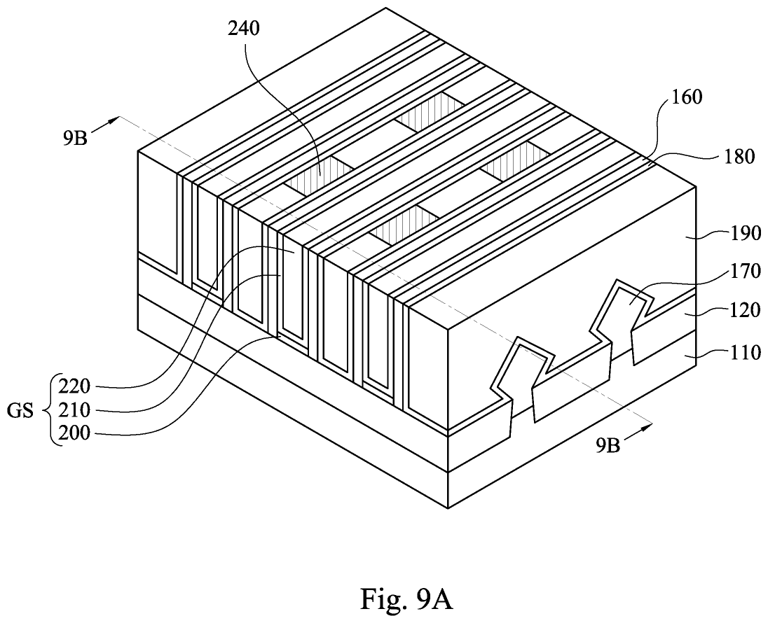

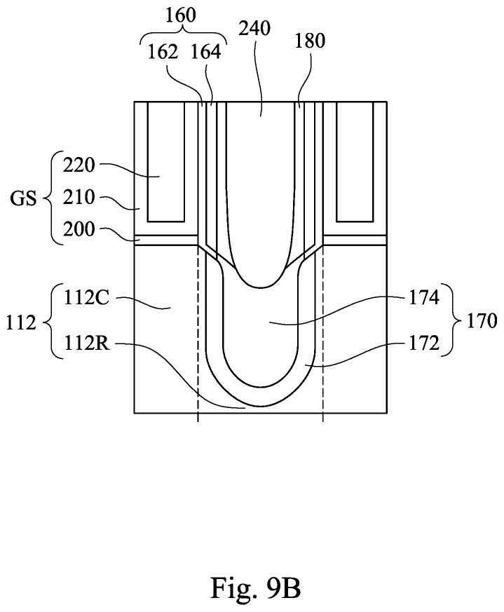

Reference is made to FIGS. 9A and 9B. FIG. 9B is a cross-sectional view taken along line 9B-9B in FIG. 9A. FIGS. 9A and 9B illustrate formations of a source/drain contact. A source/drain contact 240 is formed over the source/drain epitaxial structures 170. The source/drain contact 240 may also be referred to as a contact plug. In some embodiments, the source/drain contact formation step comprises etching source/drain contact openings through the ILD 190 and the CESL 180 to expose surfaces of the source/drain epitaxial structures 170, and deposits one or more metal materials to fill the source/drain contact openings. A CMP process may be performed to remove excess metal materials outside the source/drain contact openings, while leaving metal materials in the source/drain contact openings to serve as the source/drain contacts 240. The one or more metal materials may include W, Ru, Co, Cu, Ti, TiN, Ta, TaN, Mo, Ni, the like or combinations thereof. The one or more metal materials may be deposited by suitable deposition techniques (e.g., CVD, PVD, ALD, the like or combinations thereof). In some embodiments, a bottom end of the source/drain contact 240 may be lower than a bottom end of the gate spacer 160. In some other embodiments, a metal silicide may be formed between the source/drain contact 240 and the underlying source/drain epitaxial structure 170 for reducing contact resistance.

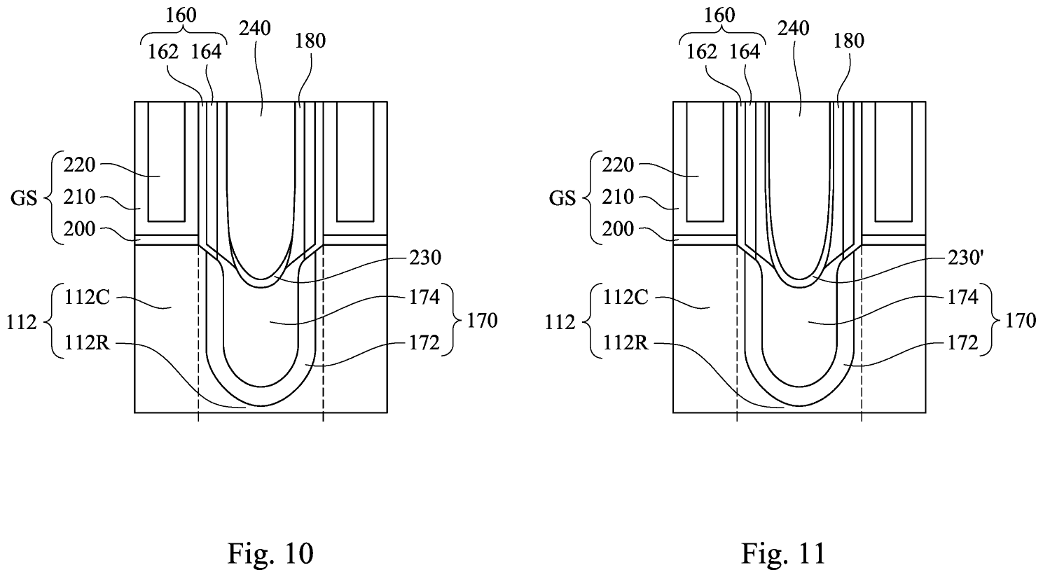

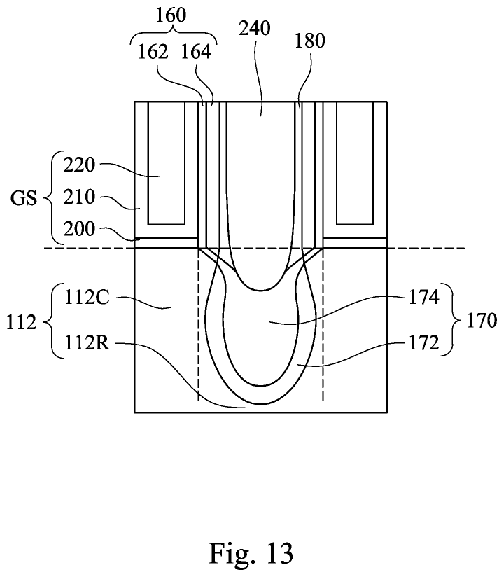

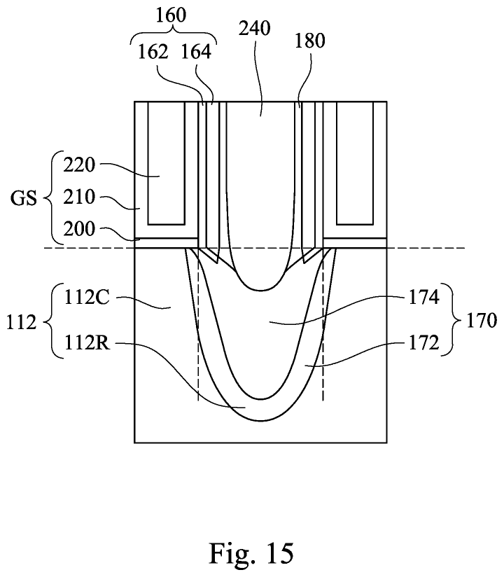

FIG. 10 illustrates a semiconductor device according to some embodiments of the present disclosure. Details of the present embodiments are similar to that of the embodiments of FIG. 9B, except that: a silicide region 230 is formed between the source/drain contacts 240 and the source/drain epitaxial structures 170. In some embodiments, after etching source/drain contact openings and prior to depositing the metal materials of the source/drain contacts 240, a silicide region 230 may be formed on the exposed surfaces of the source/drain epitaxial structures 170 by using a silicidation process. Silicidation may be formed by blanket depositing a metal layer over the exposed source/drain epitaxial structures 170, annealing the metal layer such that the metal layer reacts with silicon (and germanium if present) in the source/drain epitaxial structures 170 to form the metal silicide regions 230, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. The configuration of the silicide region 230 is applicable to other embodiments of the present disclosure (e.g., the following embodiments of FIG. 13 and FIG. 15). Other details of the present embodiments are similar to those described in previous embodiments, and therefore not repeated herein.

FIG. 11 illustrates a semiconductor device according to some embodiments of the present disclosure. Details of the present embodiments are similar to that of the embodiments of FIG. 9B, except that: a silicide liner 230′ is formed between the source/drain contacts 240 and the source/drain epitaxial structures 170. In some embodiments, after etching source/drain contact openings and prior to depositing the metal materials of the source/drain contacts 240, a silicide liner 230′ may be formed in source/drain contact openings. The formation of the silicide liner 230′ may include blanket depositing a semiconductor layer into the source/drain contact openings, depositing a metal layer over the semiconductor layer, annealing the metal layer such that the metal layer reacts with silicon (and germanium if present) in the semiconductor layer to form the metal silicide liner 230′, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. The configuration of the silicide liner 230′ is applicable to other embodiments of the present disclosure (e.g., the following embodiments of FIG. 13 and FIG. 15). Other details of the present embodiments are similar to those described in previous embodiments, and therefore not repeated herein.

FIGS. 12A, 12B, and 13 illustrate a semiconductor device according to some embodiments of the present disclosure. FIG. 12A shows the formation of the source/drain epitaxial structure 170 in the recess R1′. FIG. 12B is an enlarge view of FIG. 12A. FIG. 13 illustrates the semiconductor device after the formation of source/drain contact. Details of the present embodiments are similar to that of the embodiments of FIGS. 1-9B, except that: in the present embodiments, the source/drain epitaxial structure 170 may have a barrel shape. For example, referring to the middle width of the source/drain epitaxial structure 170 (e.g., measured at the plane HL2) is greater than the top width and bottom width of the source/drain epitaxial structure 170 (e.g., measured respectively at the planes HL1 and HL3).

As aforementioned, the profile of the recess R1′ and/or the source/drain epitaxial structures 170 can be at least described by push values at various levels (e.g., push values P1, P2, and P3 at three levels) in a XY coordinate system, which may be defined by two axes x and y at right angles to each other. In the present embodiments, the push value P1 positive, and the push value P1 is greater the push value P2. For example, a result of subtracting the push value P2 from the push value P1 is greater than about 10% of an absolute value of the push value P1/P2. When the push value P1 is positive, the point Z1 at the sidewall RS/170S is directly below the gate spacer 160. Other details of the present embodiments are similar to those described in previous embodiments, and therefore not repeated herein.

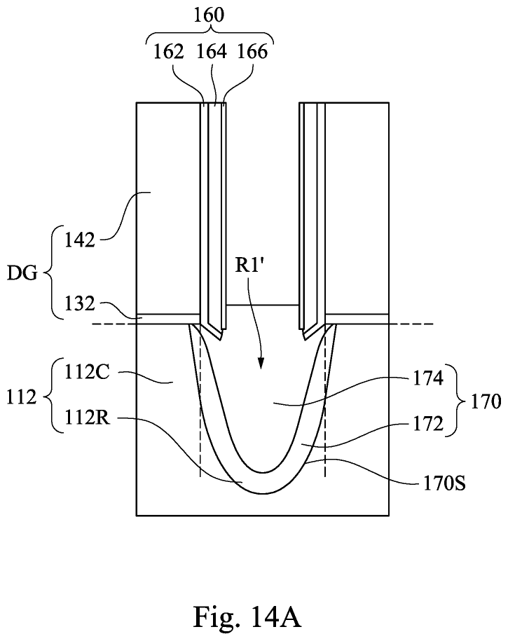

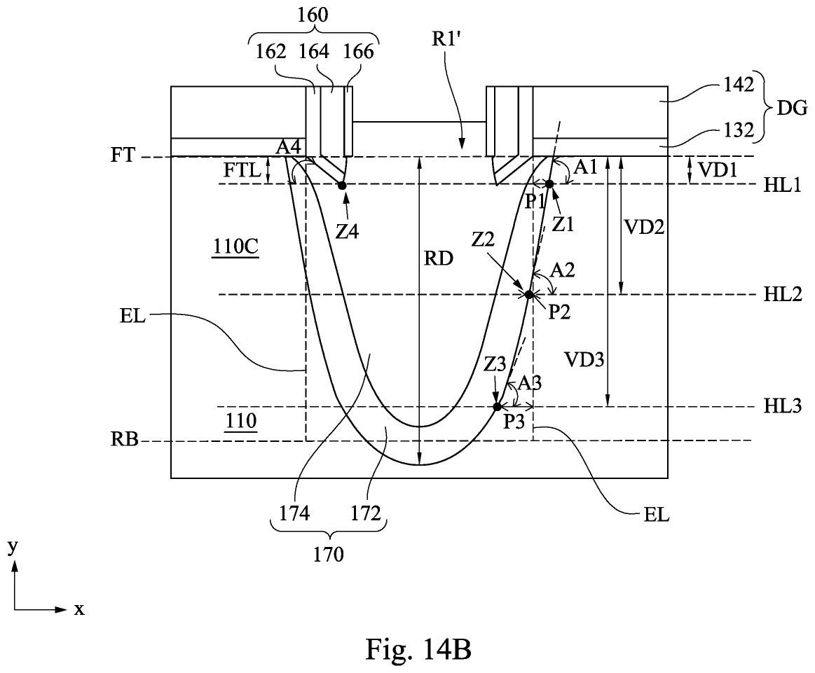

FIGS. 14A, 14B, and 15 illustrate a method of manufacturing a semiconductor device at various stages in accordance with some embodiments. FIG. 14A shows the formation of the source/drain epitaxial structure 170 in the recess R1′. FIG. 14B is an enlarge view of FIG. 14A. FIG. 15 illustrates the semiconductor device after the formation of source/drain contact. Details of the present embodiments are similar to that of the embodiments of FIGS. 1-9B, except that: in the present embodiments, the source/drain epitaxial structure 170 may have an upside-down bell shape. For example, the top width of the source/drain epitaxial structure 170 (e.g., measured at the plane HL1) is greater than the middle width and bottom width of the source/drain epitaxial structure 170 (e.g., measured respectively at the planes HL2 and HL3), and the middle width of the source/drain epitaxial structure 170 (e.g., measured at the plane HL2) is greater than the bottom width of the source/drain epitaxial structure 170 (e.g., measured at the plane HL3).

As aforementioned, the profile of the recess R1′ and/or the source/drain epitaxial structures 170 can be at least described by push values at various levels (e.g., push values P1, P2, and P3 at three levels) in a XY coordinate system, which may be defined by two axes x and y at right angles to each other. In the present embodiments, the push value P1 is negative, and the push value P1 is less the push value P2. For example, a result of subtracting the push value P2 from the push value P1 is less than about −10% of an absolute value of the push value P1/P2. In some embodiments of FIG. 6C, the push value P1, P2, P3 may be respectively ranging from about −5 nanometers to about 0 nanometers, about −3 nanometers to about 5 nanometers, and about 0 nanometer to about 15 nanometers, in which a difference between the push values P1 and P2 may be less than 5 nanometers, and a difference between the push values P2 and P3 may be less than 10 nanometers. When the push value P1 is negative, the point Z1 at the sidewall RS/170S is directly below the gate structure GS. In the present embodiments, a top end of the sidewall 170S of the source/drain epitaxial structure 170 is in contact with a bottom surface of a gate dielectric layer (e.g., the interfacial layer 200 and a high-k dielectric layer 210) of the gate structure GS. Other details of the present embodiments are similar to those described in previous embodiments, and therefore not repeated herein.

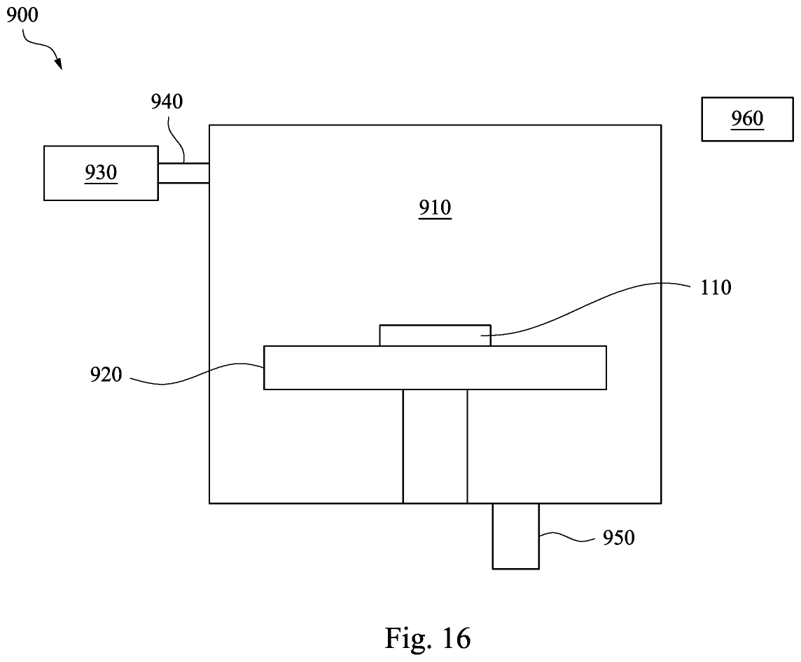

FIG. 16 is a schematic view of an apparatus 900 for the in-situ etching and epitaxy process according to some embodiments of the present disclosure. The dry etcher 800 may include a chamber 910, a stage 920, a gas source 930, a gas delivery system 940, a gas extraction system 950, and a temperature controller 960. The aforementioned control parameters (e.g., pressure, temperature, gas type) may be assigned to these components of the dry etcher 900. For example, the gas type may be assigned to the gas source 930. The pressure and the gas flow may be assigned to the gas delivery system 940 and the gas extraction system 950.

The stage 920 may be disposed at the bottom portion of the chamber 910 for supporting the substrate 110. The gas source 930 may be configured to provide suitable gas types (e.g., HCl, Cl₂, GeH₄, GeCl₄) for process gas. The gas delivery system 940 may be connected between the gas source 930 and a gas inlet of the chamber 910, thereby introducing the process gas into the chamber 910. The gas delivery system 940 may include suitable mass flow controller (MFC) to control the gas flow. The gas extraction system 950 may connecting a pump to a gas outlet of the chamber 910, and may include valves to controlling the pressure in the chamber 910.

An in-situ etching and epitaxy process using the apparatus 900 is described. First, a substrate 110 is placed on the stage 920 in the chamber 910. Subsequently, the chamber 910 is evacuated to a certain degree of vacuum. For example, for the aforementioned recess modifying etching process, a pressure in the chamber 910 is in a range from about 10 torr to about 300 torr. Subsequently, a process gas is introduced through the gas delivery system 940 into the chamber 810. The gas extraction system 950 may adjust the pressure of the process gas in the chamber 910, for example, by opening or closing an exhaust valve. The temperature controller 960 may be use to control an etch temperature or deposition temperature. For example, for the aforementioned recess modifying etching process, an etch temperature is in a range from about 400° C. to about 700° C.

Based on the above discussions, it can be seen that the present disclosure offers advantages over FinFET devices. It is understood, however, that other embodiments may offer additional advantages, and not all advantages are necessarily disclosed herein, and that no particular advantage is required for all embodiments. One advantage is that a desired recess profile with close proximity between source/drain and channel near fin-top is formed in recessed source and drain. This recess profile can boost strain exerted on channel by epitaxy SID therefor boost the channel mobility and reduce channel resistance to achieve better device performance. Another advantage is that the desired recess profile may be formed by an in-situ gas-phase etching in S/D process, thereby avoiding surface impurity residue. Still another advantage is that the fabrication method can be compatible with epitaxy process and possess better surface roughness and lower interface impurity. Still another advantage is that the fabrication method can be implemented in planar, FinFET, nanosheet devices.

According to some embodiments of the present disclosure, a method for manufacturing a semiconductor device is provided. The method includes forming a semiconductor fin over a semiconductor substrate; forming a gate structure over a first portion of the semiconductor fin; etching a source/drain recess in a second portion of the semiconductor fin; and performing an in-situ source/drain etching and epitaxy process to form a source/drain epitaxial structure over the second portion of the semiconductor fin. Performing the in-situ source/drain etching and epitaxy process comprises: performing a dry etching process to adjust a profile of the source/drain recess in a chamber; and after adjusting the dry etching process, epitaxially growing the source/drain epitaxial structure in the source/drain recess in the chamber.

According to some embodiments of the present disclosure, a method for manufacturing is provided. The method includes forming a semiconductor fin over a semiconductor substrate; forming a gate structure over a first portion of the semiconductor fin; performing a first etching process to etch a source/drain recess in a second portion of the semiconductor fin; performing a second etching process to push a sidewall of the source/drain recess toward the first portion of the semiconductor fin; and after the second etching process, epitaxially growing a source/drain epitaxial structure in the source/drain recess.

According to some embodiments of the present disclosure, a semiconductor device includes a semiconductor substrate, a gate structure, a gate spacer, and a source/drain epitaxial structure. The semiconductor substrate includes a semiconductor fin. The gate structure is over a first portion of the semiconductor fin. The gate spacer is at a sidewall of the gate structure. The source/drain epitaxial structure is over a second portion of the semiconductor fin. The source/drain epitaxial structure has a sidewall facing the first portion of the semiconductor fin, and a top end of the sidewall of the source/drain epitaxial structure is directly below the gate spacer or the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a semiconductor fin over a semiconductor substrate;
forming a gate structure over a first portion of the semiconductor fin;
etching a source/drain recess in a second portion of the semiconductor fin; and
performing an in-situ source/drain etching and epitaxy process to form a source/drain epitaxial structure over the second portion of the semiconductor fin, wherein performing the in-situ source/drain etching and epitaxy process comprises:
performing a dry etching process to adjust a profile of the source/drain recess in a chamber; and
after the dry etching process, epitaxially growing the source/drain epitaxial structure in the source/drain recess in the chamber.

2. The method of claim 1, wherein the dry etching process is performed using gas-phase etchant without using a plasma.

3. The method of claim 2, wherein etching the source/drain recess is performed using a plasma etching process.

4. The method of claim 1, wherein etching the source/drain recess is performed using a fluorine-based chemistry, and the dry etching process is performed using a chlorine-based chemistry.

5. The method of claim 1, wherein the in-situ source/drain etching and epitaxy process is performed without vacuum break.

6. The method of claim 1, wherein the dry etching process is performed with a temperature in the chamber in a range from 400° C. to 700° C., and a pressure in the chamber in a range from 10 torr to 300 torr.

7. The method of claim 1, further comprising:
forming a gate spacer at a sidewall of the gate structure prior to etching the source/drain recess, wherein the in-situ source/drain etching and epitaxy process is performed such that a top portion of the source/drain epitaxial structure extends beyond a sidewall of the gate spacer facing away from the gate structure.

8. The method of claim 1, wherein the in-situ source/drain etching and epitaxy process is performed such that a top portion of the source/drain epitaxial structure extends to a position directly below the gate structure.

9. A method for manufacturing a semiconductor device, comprising:
forming a semiconductor fin over a semiconductor substrate;
forming a gate structure over a first portion of the semiconductor fin;
performing a first etching process to etch a source/drain recess in a second portion of the semiconductor fin;
performing a second etching process to push a sidewall of the source/drain recess toward the first portion of the semiconductor fin; and
after the second etching process, epitaxially growing a source/drain epitaxial structure in the source/drain recess.

10. The method of claim 9, wherein the second etching process is a dry etch process without using a plasma.

11. The method of claim 9, wherein the second etching process is performed such that the source/drain recess is deepened.

12. The method of claim 9, further comprising:
forming a gate spacer at a sidewall of the gate structure prior to the first etching process, wherein the first etching process is performed such that a bottom surface of the gate spacer is in contact with the semiconductor substrate, the second etching process is performed such that at least a portion of the bottom surface of the gate spacer is exposed by the source/drain recess.

13. The method of claim 12, wherein epitaxially growing the source/drain epitaxial structure is performed such that the source/drain epitaxial structure is in contact with the exposed portion of the bottom surface of the gate spacer.

14. The method of claim 13, wherein an interface between the bottom surface of the gate spacer and the source/drain epitaxial structure is inclined with respect to a top surface of the semiconductor substrate.

15. A semiconductor device, comprising:
a semiconductor substrate comprising a semiconductor fin;
a gate structure over a first portion of the semiconductor fin;
a gate spacer at a sidewall of the gate structure; and
a source/drain epitaxial structure over a second portion of the semiconductor fin, wherein the source/drain epitaxial structure has a sidewall facing the first portion of the semiconductor fin, and a top end of the sidewall of the source/drain epitaxial structure is directly below the gate spacer or the gate structure.

16. The semiconductor device of claim 15, wherein the top end of the sidewall of the source/drain epitaxial structure is in contact with a bottom surface of the gate spacer.

17. The semiconductor device of claim 15, wherein the top end of the sidewall of the source/drain epitaxial structure is in contact with a bottom surface of a gate dielectric layer of the gate structure.

18. The semiconductor device of claim 15, wherein a bottom surface of the gate spacer is inclined with respect to a top surface of the semiconductor substrate.

19. The semiconductor device of claim 15, wherein the source/drain epitaxial structure is U-shaped.

20. The semiconductor device of claim 15, wherein the source/drain epitaxial structure has a first width at a first level, the source/drain epitaxial structure has a second width at a second level, the first level is higher than the second level, the second level is at a vertical middle between a bottom of the source/drain epitaxial structure and a top of the semiconductor fin, and the first width is substantially equal to or greater than the second width.
